(19) United States
(12) Patent Application Publication
(10) Pub. No.: US 2024/0012955 A1
(43) Pub. Date: Jan. 11, 2024

(54) GENERATIVE NETWORK-BASED FLOOR PLAN GENERATION

(71) Applicant: Accenture Global Solutions Limited, Dublin 4 (IE)

(72) Inventors: Kumar ABHINAV, Hazaribag (IN); Alpana DUBEY, Bangalore (IN)

(73) Assignee: Accenture Global Solutions Limited, Dublin 4 (IE)

(21) Appl. No.: 18/349,466

(22) Filed: Jul. 10, 2023

(30) Foreign Application Priority Data
Jul. 8, 2022 (IN) 202211039341

(51) Int. Cl. G06F 30/13

(52) U.S. Cl. CPC G06F 30/13

(57) ABSTRACT

In some examples, generative network-based floor plan generation may include receiving, for a floor plan that is to be classified, a layout graph for which user constraints are encoded as a plurality of room types. The user constraints may include spatial connections therebetween. Based on the layout graph, embedding vectors for each room type of the plurality of room types may be generated. Bounding boxes and segmentation masks may be determined for each room embedding from the layout graph, and based on an analysis of the embedding vectors. A space layout may be generated by combining the bounding boxes and the segmentation masks. The floor plan may be generated based on an analysis of the space layout, and synthesized based on the space layout, noise, and a contextual graph embedding to generate a synthesized floor plan. The synthesized floor plan may be classified as authentic or not-authentic.

### PRIORITY

The present application claims priority under 35 U.S.C. 119(a)-(d) to commonly assigned and co-pending Indian Patent Application Serial Number 202211039341, filed Jul. 8, 2022, the disclosure of which is hereby incorporated by reference in its entirety.

### BACKGROUND

With respect to floor plan design of residential as well as non-residential facilities, tools, such as computer-aided design (CAD) tools, may be used to design a floor plan. Depending on the complexity of the floor plan design, various levels of expertise may be required for utilization of such tools. In an example of a floor plan design, an architect may obtain the requirements from a client in the form of room types, number of rooms, room sizes, plot boundary, the connection between rooms, etc., sketch out rough floor plans and collect feedback from the client, refine the sketched plans, and design and generate the floor plan using CAD tools.

### BRIEF DESCRIPTION OF DRAWINGS

Features of the present disclosure are illustrated by way of example and not limited in the following figure(s), in which like numerals indicate like elements, in which:

FIG. 1 illustrates a layout of a generative network-based floor plan generation apparatus in accordance with an example of the present disclosure;

FIG. 2 illustrates an architecture of the generative network-based floor plan generation apparatus of FIG. 1, in accordance with an example of the present disclosure;

FIG. 3 illustrates details of a space layout network analyzer of the generative network-based floor plan generation apparatus of FIG. 1, in accordance with an example of the present disclosure;

FIG. 4 illustrates a bounding regression network of the space layout network analyzer of the generative network-based floor plan generation apparatus of FIG. 1, in accordance with an example of the present disclosure;

FIG. 5 illustrates a mask regression network of the space layout network analyzer of the generative network-based floor plan generation apparatus of FIG. 1, in accordance with an example of the present disclosure;

FIG. 6 illustrates an image synthesizer architecture of the generative network-based floor plan generation apparatus of FIG. 1, in accordance with an example of the present disclosure;

FIG. 7 illustrates a spade of the image synthesizer of FIG. 6, in accordance with an example of the present disclosure;

FIG. 8 illustrates a residual block of the image synthesizer of FIG. 6, in accordance with an example of the present disclosure;

FIG. 9 illustrates an image encoder of the image synthesizer of FIG. 6, in accordance with an example of the present disclosure;

FIG. 10 illustrates a discriminator of the generative network-based floor plan generation apparatus of FIG. 1, in accordance with an example of the present disclosure;

FIGS. 11-12 illustrate examples of results generated by the generative network-based floor plan generation apparatus of FIG. 1, in accordance with an example of the present disclosure;

FIG. 13 illustrates an example block diagram for generative network-based floor plan generation in accordance with an example of the present disclosure;

FIG. 14 illustrates a flowchart of an example method for generative network-based floor plan generation in accordance with an example of the present disclosure; and

FIG. 15 illustrates a further example block diagram for generative network-based floor plan generation in accordance with another example of the present disclosure.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent however, that the present disclosure may be practiced without limitation to these specific details. In other instances, some methods and structures have not been described in detail so as not to unnecessarily obscure the present disclosure.

Throughout the present disclosure, the terms “a” and “an” are intended to denote at least one of a particular element. As used herein, the term “includes” means includes but not limited to, the term “including” means including but not limited to. The term “based on” means based at least in part on.

Generative network-based floor plan generation apparatuses, methods for generative network-based floor plan generation, and non-transitory computer readable media having stored thereon machine readable instructions to provide generative network-based floor plan generation are disclosed herein. The apparatuses, methods, and non-transitory computer readable media disclosed herein may provide for intuitive generation of a floor plan without requiring knowledge of complex floor plan design tools. In this regard, the apparatuses, methods, and non-transitory computer readable media disclosed herein may implement floor plan design exploration guided by multi-attribute constraints. Yet further, the apparatuses, methods, and non-transitory computer readable media disclosed herein may facilitate interactive floor plan design of a residential or non-residential facility.

The apparatuses, methods, and non-transitory computer readable media disclosed herein may represent a generative-based approach to synthesize floor plan layout that is guided by user constraints. User inputs in the form of boundary, room types, and spatial relationships may be considered to generate the layout design satisfying these requirements. Based on qualitative and quantitative analysis of metrics such as floor plan layout generation accuracy, realism, and quality, floor plans generated by the apparatuses, methods, and non-transitory computer readable media disclosed herein may provide greater realism and improved quality compared to known techniques.

With respect to floor plan design, as disclosed herein, tools, such as CAD tools, may be used to design a floor plan. Depending on the complexity of the floor plan design, various levels of expertise may be required for utilization of such tools. In this regard, it is technically challenging to generate a floor plan without expertise in floor plan design or the use of complex designing tools.

In order to address at least the aforementioned technical challenges, the apparatuses, methods, and non-transitory computer readable media disclosed herein may implement a generative model to synthesize floor plans guided by user constraints. User inputs in the form of boundary, room types, and spatial relationships may be analyzed to generate the floor plan design that satisfies these requirements. For example, the apparatuses, methods, and non-transitory computer readable media disclosed herein may receive, as input, a layout graph describing objects (e.g., types of rooms) and their relationships (e.g., connections between rooms, placement of furniture), and generate one or more realistic floor plans corresponding to the graph. The apparatuses, methods, and non-transitory computer readable media disclosed herein may utilize a graph convolution network (GCN) to process an input layout graph, which provides embedding vectors for each room type. These vectors may be used to predict bounding boxes and segmentation masks for objects, which are combined to form a space layout. The space layout may be synthesized to an image using an image synthesizer to generate a floor plan.

The architecture of the generative network-based floor plan generation apparatus may include four components that include a graph convolutional message passing network analyzer, a space layout network analyzer, an image synthesizer, and a discriminator. Generally, the apparatuses, methods, and non-transitory computer readable media disclosed herein may receive a noise vector and a layout graph with encoded user-constraints as input, and generate one or more realistic floor plans as output. The graph convolutional message passing network analyzer may process input graphs and generate embedding vectors for each room type. The space layout network analyzer may predict bounding boxes and segmentation masks for each room embedding, and combine the bounding boxes and the segmentation masks to generate a space layout. The image synthesizer may synthesize an image based on the noise vector to generate a synthesized floor plan. The discriminator may classify the synthesized floor plan as authentic or not-authentic.

With respect to techniques for floor plan generation that may define heuristics to place doors and windows, the apparatuses, methods, and non-transitory computer readable media disclosed herein may learn these heuristics from data, and predict the placement of doors and windows. Additionally, some approaches for floor plan design may require further post-processing such as fixing gaps and overlaps to make the floor plan look more realistic, and not learned from data. The apparatuses, methods, and non-transitory computer readable media disclosed herein may generate higher quality floor plan layouts without such post-processing. The apparatuses, methods, and non-transitory computer readable media disclosed herein may further provide an end-to-end trainable network to generate floor plans along with doors and windows from a given input boundary and layout graph. The generated two-dimensional (2D) floor plan may be converted to 2.5D to 3D floor plans. The aforementioned floor plan generation process may also be used to generate floor plans for a single unit or multiple units. For example, in the case of an apartment, a layout of multiple units of different configurations may be generated. The generated floor plan may be utilized to automatically (e.g., without human intervention) control (e.g., by a controller) one or more tools and/or machines related to construction of a structure specified by the floor plan. For example, the tools and/or machines may be automatically guided by the dimensional layout of the floor plan to coordinate and/or verify dimensions and/or configurations of structural features (e.g., walls, doors, windows, etc.) specified by the floor plan.

For the apparatuses, methods, and non-transitory computer readable media disclosed herein, the elements of the apparatuses, methods, and non-transitory computer readable media disclosed herein may be any combination of hardware and programming to implement the functionalities of the respective elements. In some examples described herein, the combinations of hardware and programming may be implemented in a number of different ways. For example, the programming for the elements may be processor executable instructions stored on a non-transitory machine-readable storage medium and the hardware for the elements may include a processing resource to execute those instructions. In these examples, a computing device implementing such elements may include the machine-readable storage medium storing the instructions and the processing resource to execute the instructions, or the machine-readable storage medium may be separately stored and accessible by the computing device and the processing resource. In some examples, some elements may be implemented in circuitry.

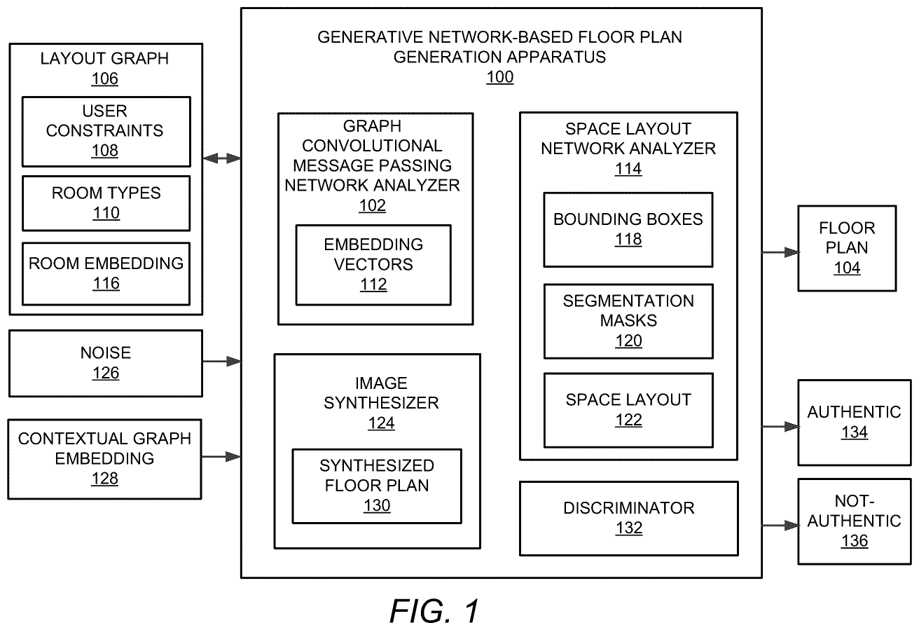

FIG. 1 illustrates a layout of an example generative network-based floor plan generation apparatus (hereinafter also referred to as “apparatus 100”).

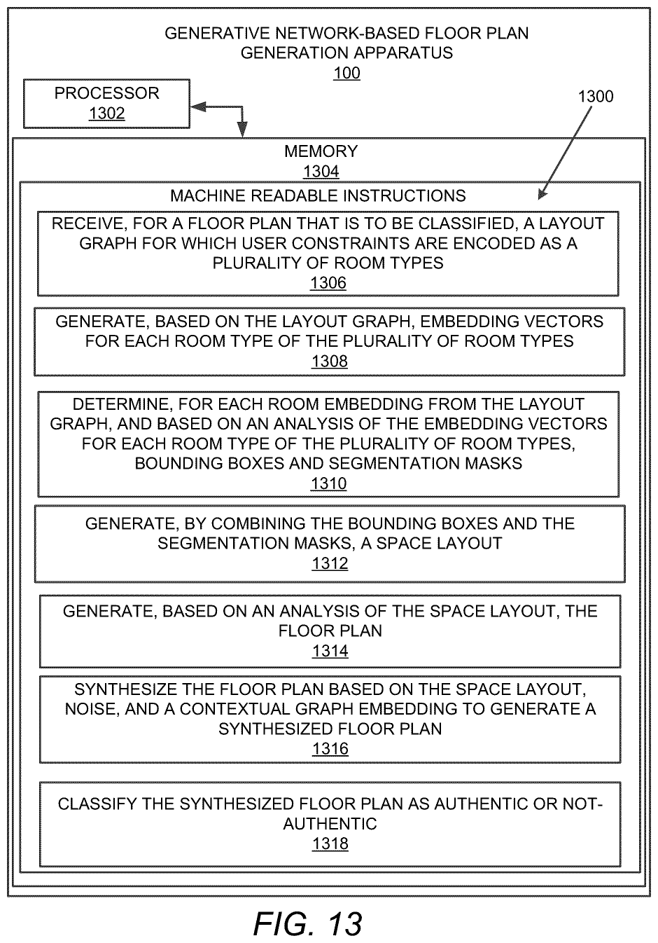

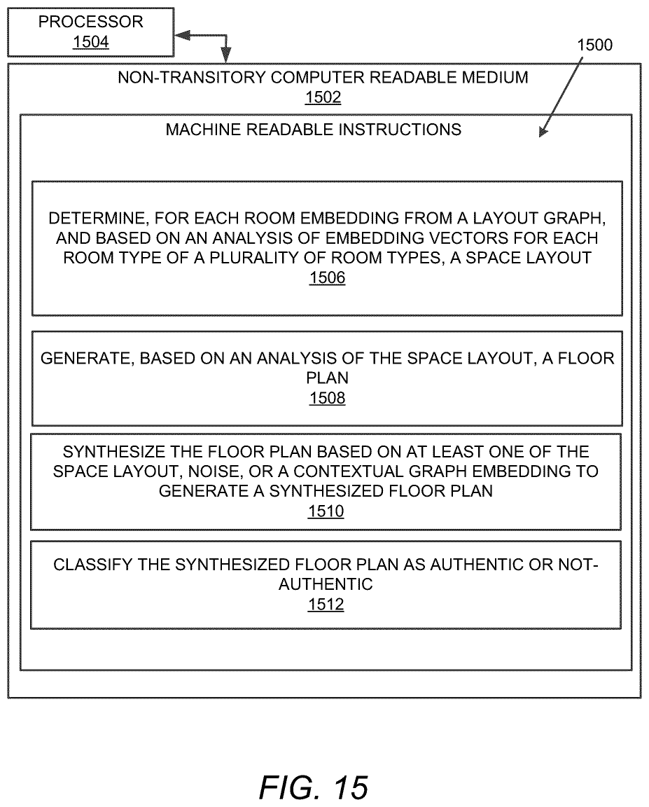

Referring to FIG. 1, the apparatus 100 may include a graph convolutional message passing network analyzer 102 that is executed by at least one hardware processor (e.g., the hardware processor 1302 of FIG. 13, and/or the hardware processor 1504 of FIG. 15) to receive, for a floor plan 104 that is to be classified, a layout graph 106 for which user constraints 108 are encoded as a plurality of room types 110. The user constraints 108 may include spatial connections therebetween. The graph convolutional message passing network analyzer 102 may generate, based on the layout graph 106, embedding vectors 112 for each room type of the plurality of room types 110.

A space layout network analyzer 114 that is executed by at least one hardware processor (e.g., the hardware processor 1302 of FIG. 13, and/or the hardware processor 1504 of FIG. 15) may determine, for each room embedding 116 from the layout graph 106, and based on an analysis of the embedding vectors 112 for each room type of the plurality of room types 110, bounding boxes 118 and segmentation masks 120. The space layout network analyzer 114 may generate, by combining the bounding boxes 118 and the segmentation masks 120, a space layout 122.

An image synthesizer 124 that is executed by at least one hardware processor (e.g., the hardware processor 1302 of FIG. 13, and/or the hardware processor 1504 of FIG. 15) may generate, based on an analysis of the space layout 122, the floor plan 104. Further, the image synthesizer 124 may synthesize the floor plan 104 based on the space layout 122, noise 126, and a contextual graph embedding 128 to generate a synthesized floor plan 130.

A discriminator 132 that is executed by at least one hardware processor (e.g., the hardware processor 1302 of FIG. 13, and/or the hardware processor 1504 of Figure may classify the synthesized floor plan 104 as authentic 134 or not-authentic 136.

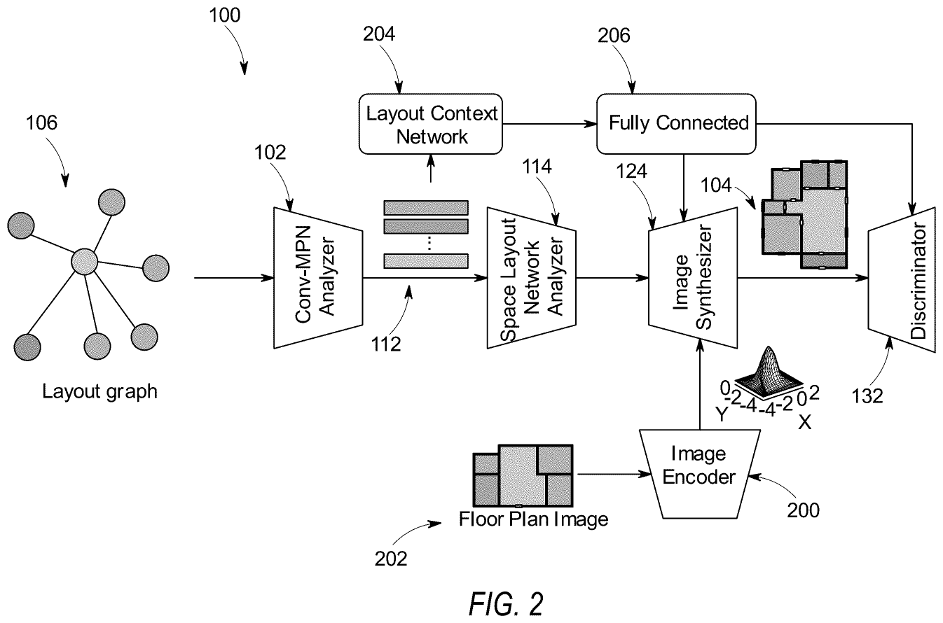

FIG. 2 illustrates an architecture of the generative network-based floor plan generation apparatus 100, in accordance with an example of the present disclosure.

Referring to FIG. 2, the architecture of the apparatus 100 may include the graph convolutional message passing network analyzer 102, the space layout network analyzer 114, the image synthesizer 124, and the discriminator 132. The graph convolutional message passing network analyzer 102 may process the layout graph 106 that encodes user constraints as room types and their spatial connections, and generate the embedding vectors 112 for each room type. An embedding vector may denote a compact feature representation for each type of room (node).

The space layout network analyzer 114 may predict the bounding boxes 118 and the segmentation masks 120 for each room embedding 116 from the layout graph 106, and combine the bounding boxes 118 and the segmentation masks 120 to generate the space layout 122. A bounding box may be used to describe the spatial location of an object. A mask may represent a binary image including zero and non-zero values. A space layout may represent an aggregation of bilinear interpolation of a bounding box and a mask for each room type (e.g., node).

The image synthesizer 124 may synthesize the floor plan 104 conditioned on the space layout 122, noise 126, and contextual graph embedding 128. Random noise may generally include a Gaussian function passed to the image synthesizer 124. However, instead of random noise, parameters such as mean and variance may be generated from a dataset. A contextual graph embedding may capture the compact representation of the spatial relation of a room.

The discriminator 132 may classify the synthesized floor plan 104 as authentic 134 or not-authentic 136. In this regard, an authentic floor plan may ensure that the generated floor plans look realistic.

The graph convolutional message passing network analyzer 102, the space layout network analyzer 114, the image synthesizer 124, and the discriminator 132 may be trainable to generate rooms, walls, doors, and windows.

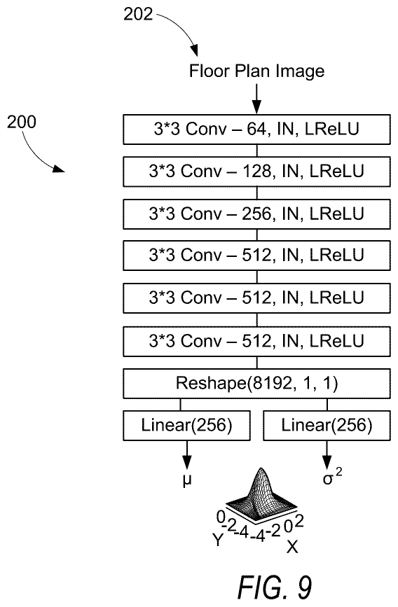

Image encoder 200 may encode a real image (e.g., floor plan image 202) to a latent representation for generating a mean vector and a variance vector. In this regard, an authentic (e.g., real floor plan) may be passed through a series of layers (shown in FIG. 9) to represent into a feature representation to generate mean and variance values determined through linear layers. The mean vector and a variance vector may be used to determine the noise input to the image synthesizer 124 via reparameterization. Reparameterization may allow the mean and variance vectors to remain as the learnable parameters of the network while still maintaining the stochasticity of the entire system. Thus, the image encoder 200 may generate, based on the floor plan, mean and variance vectors, and determine, based on the mean and variance vectors, the noise.

A layout graph context network 204 may pool the features generated from the graph convolutional message passing network analyzer 102. Pooling may be used to summarize the feature vector through functions such as Max, Avg., Min., etc. Each feature vector when pooled may be reduced to a scalar value. The scalar value of all of the room types may be concatenated and passed through the layout graph context network 204. These pooled context features may then be passed to a fully-connected layer 206 that generates embeddings that are provided to both the image synthesizer 124 and the discriminator 132 during training. The fully-connected layer 206 may represent a linear layer for processing input values.

In some examples, the image synthesizer 124 may receive an input boundary feature map (e.g., B as a 256×256 image). The graph convolutional message passing network analyzer 102 may receive the layout graph 106 with encoded user-constraints G as input, and the image synthesizer 124 may generate the realistic floor plan 104 (e.g., floor plan layout L) as output. Thus, the image synthesizer 124 may receive an input boundary feature map, and generate, based on an analysis of the space layout and the input boundary feature map, the floor plan. The input boundary feature map may be represented as a 256×256 image. The nodes of the layout graph 106 may be denoted room types, and the edges may be denoted connections between the rooms. Each node may be represented as a tuple (η, lᵢ, sᵢ); where rᵢ∈R^{d}^{₁} is a room embedding (R being the possible categories of room types), lᵢ∈(0, 1)^{d2} is a location vector, and sᵢ∈(0, 1)^{d3} is a size vector. The embedding size d₁ may be set to 128, d₂ may be set to 25 to denote a coarse image location using a 5×5 grid, and d₃ may be set to 10 to denote the size of a room using different scales.

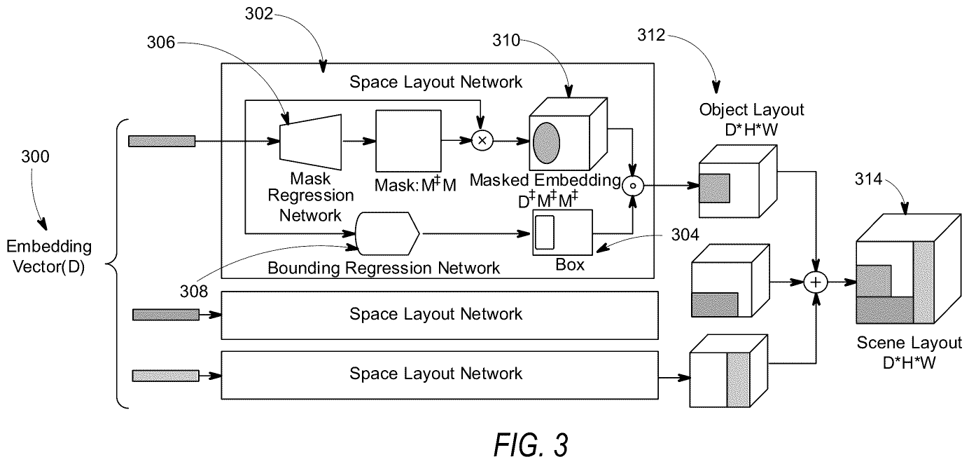

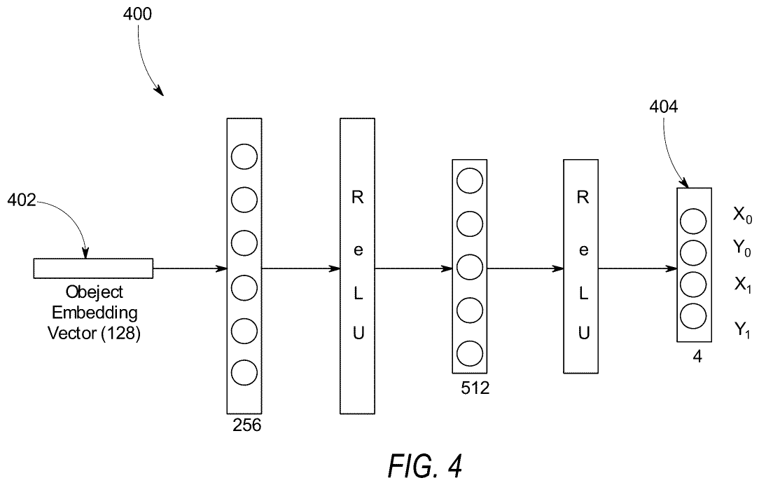

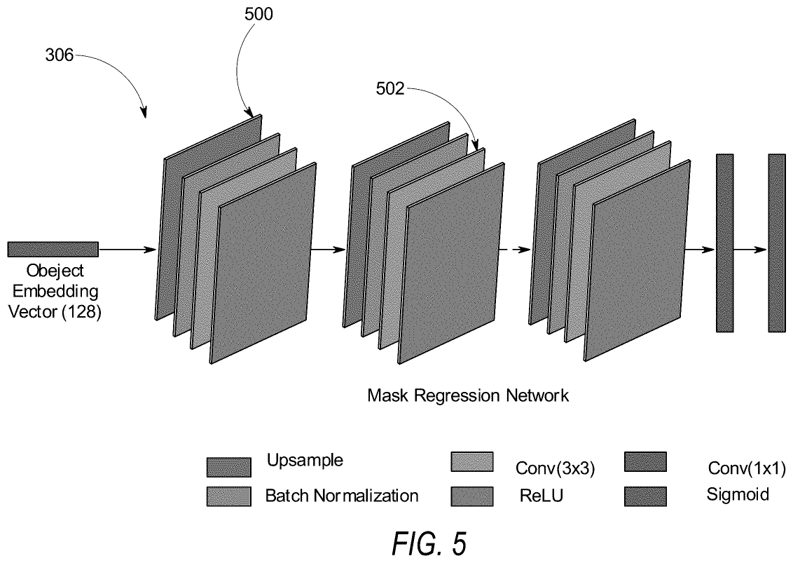

FIG. 3 illustrates details of the space layout network analyzer 114, in accordance with an example of the present disclosure. FIG. 4 illustrates a bounding regression network 400 of the space layout network analyzer 114, in accordance with an example of the present disclosure. Further, FIG. 5 illustrates a mask regression network of the space layout network analyzer 114, in accordance with an example of the present disclosure.

With respect to the graph convolutional message passing network analyzer 102, the layout graph 106 may be passed through a series of graph convolution layers (e.g., a message passing network) which generates embedding vectors for each node (e.g., a room). The graph convolutional message passing network analyzer 102 may utilize embedding layers to embed the room types and relationships in the layout graph 106 to produce vectors of dimension Dᵢₙ=128. Given an input graph with vectors of dimension D 1 at each node and edge, the graph convolutional message passing network analyzer 102 may determine new vectors of dimension Dour for each node and edge. Output vectors may be a function of a neighborhood of their corresponding inputs so that each graph convolution layer propagates information along edges of the layout graph 106.

With respect to the graph convolutional message passing network analyzer 102, a graph neural network (GNN) of the graph convolutional message passing network analyzer 102 may represent a deep neural network that uses a graph data structure to capture the dependence of data. The GNN may adopt a message-passing strategy to update the representation of a node by aggregating transformed messages (representations) of its neighboring nodes. After T iterations of message passing, a node's representation may capture dependence from all the nodes within a t-hop neighborhood. Formally, a node Vs representations at eh layer may be defined as follows:

mᵤ^{(t)}=MSG.^{(t)}(hᵤ^{(t-1}),u∈{ [symbol] (v)∪v}hᵥ^{(t)}=AGG.^{(t)}({mᵤ^{(t)},u∈ [symbol] (v)},m_{c}^{(t)})

In this regard, h^{(t)} may represent the feature representation of node v at t^{th} layer, m^{(t)} may represent the transformed message from neighborhood node u, and N (v) may represent the set of nodes adjacent to v. MSG may represent the message transformation at a particular node, and AGG may represent the aggregation function implemented, for example, as a Multi-Layer Perceptron (MLP) aggregation, to capture the messages from neighboring nodes.

Referring to FIG. 3, an embedding vector 300, generated by graph convolutional message passing network analyzer 102, for each room type may be passed to the space layout network analyzer 114 that may utilize a space layout network 302 (e.g., three space layout networks shown), which may predict a layout for an object (e.g., room type). The space layout network analyzer 114 may predict a soft binary segmentation mask and a bounding box 304 for each room type. The space layout network analyzer 114 may receive an embedding vector in of shape ‘D’ (128 for example) for room type rᵢ, and pass the embedding vector to a mask regression network 306 (e.g., see also FIG. 5) to predict a soft binary mask rmᵢ of shape M*M and a box regression network 308 to predict a bounding box bᵢ=(x₀; y₀; x₁; y₁), where x₀; x₁ are the left and right coordinates, and y₀; y₁ are the top and bottom coordinates of the box.

Referring to FIGS. 3 and 5, the mask regression network 306 may include of a sequence of upsampling and convolution layers (e.g., 500 and 502) with sigmoid nonlinearity so that elements of the mask lie in the range (0; 1) and the box regression network may be a Multi-layer Perceptron (MLP). Upsampling may double the dimensions of an input. An upsample layer may include 2*2 nearest-neighbor upsampling. Convolution layers may be used to extract features and reduce the spatial dimensions.

With respect to FIG. 4, the bounding regression network 400 may utilize a fully connected network (e.g., linear layer) having input embeddings of 128 (room type embedding) as shown at 402. The input layer may be followed by several hidden layers of size 512, 256, and 4. The final hidden layer at 404 may predict four coordinate values.

The embedding vector of each room type it; may be multiplied element-wise with their mask rmᵢ to generate a masked embedding of shape D*M*M at 310, which may then be warped to the position of the bounding box using bi-linear interpolation to generate a room layout 312. Space layout 314 may represent the sum of all of the room layouts. A similar approach may be implemented to generate walls and door masks. During training, ground truth bounding boxes may be utilized for each room type to compare with the predicted bounding boxes. However, during inference time, the predicted bounding boxes bi may be utilized.

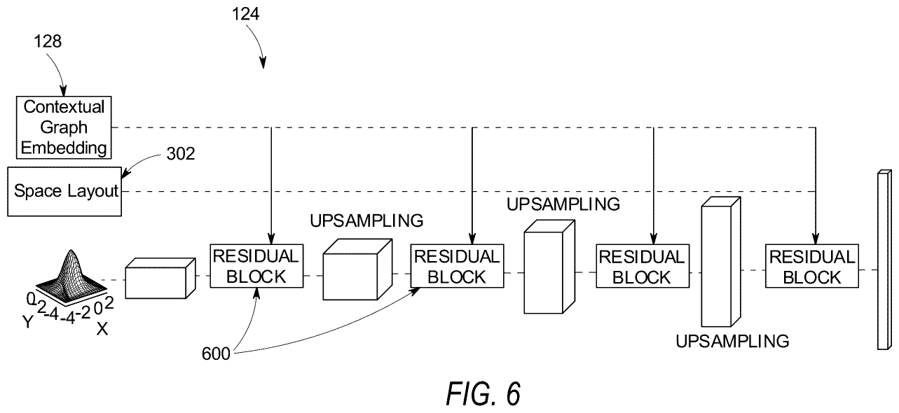

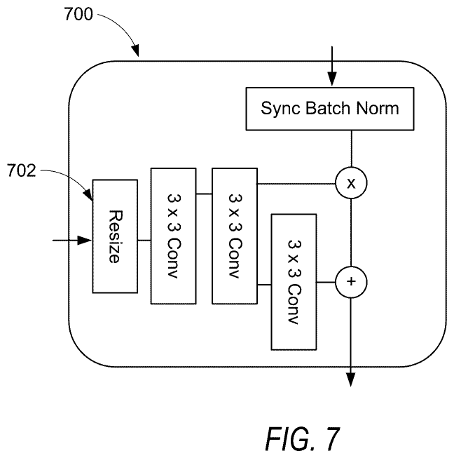

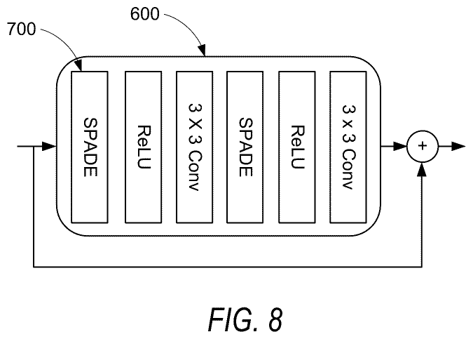

FIG. 6 illustrates an image synthesizer architecture of the apparatus 100, in accordance with an example of the present disclosure. FIG. 7 illustrates a spade 700 of the image synthesizer 124, in accordance with an example of the present disclosure. FIG. 8 illustrates a residual block of the image synthesizer 124, in accordance with an example of the present disclosure. Further, FIG. 9 illustrates an image encoder 200 of the image synthesizer 124, in accordance with an example of the present disclosure.

Referring to FIGS. 6 and 8, the image synthesizer 124 may include a series of the residual blocks 600 with nearest neighbor upsampling layers. A residual block may include a series of upsampling layers with spatially adaptive normalization. FIGS. 7 and 8 combined may represent a residual block.

Referring to FIG. 7, the modulation parameters of all the normalization layers may be learned using a spade 700. The spade 700 may represent a spatially-adaptive normalization layer for synthesizing photorealistic images. Since each residual block operates at a different scale, a segmentation map may be resized at 702 to match the resolution of the corresponding feature map using nearest-neighbor downsampling.

Referring to FIG. 9, the image encoder 200 may encode a real image (e.g., the floor plan image 202) to a latent representation for generating a mean vector and a variance vector. The mean vector and a variance vector may be used to determine the noise input to the image synthesizer 124 via reparameterization. The layout graph context network 204 may pool the features generated from the graph convolutional message passing network analyzer 102. These pooled context features may then be passed to the fully-connected layer 206 that generates embeddings that are provided to both the image synthesizer 124 and the discriminator 132 during training. The layout graph context network 204 may provide for images to appear realistic, as well as account for the layout graph relationships. Mean (μ) and variance (σ²) may be learnable parameters learned through image encoder 200, as opposed to utilization of random values generated, for example, by a Gaussian function.

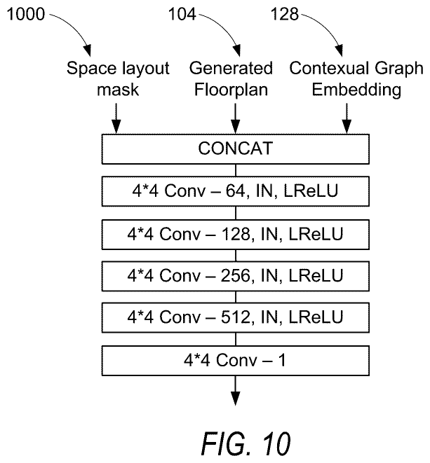

FIG. 10 illustrates the discriminator 132, in accordance with an example of the present disclosure.

Referring to FIG. 10, the discriminator 132 may receive concatenation of a space layout mask 1000 and the output image (e.g., the synthesized floor plan 130) from the image synthesizer 124 as input, and classify the synthesized floor plan 104 as authentic 134 or not-authentic 136. Space layout mask 1000 may represent the bilinear interpolation of bounding box and mask for each room type (e.g., node). In this regard, realistic output images may be generated by training an image generation network f adversarially against a discriminator network D (e.g., the discriminator 132). The discriminator network D may classify the input floor plan x (e.g., the synthesized floor plan 104) as authentic 134 (e.g., real) or not-authentic 136 (e.g., fake) by maximizing objective as follows:

$${ℒ}_{GAN} = {𝔼}_{x \sim {p}_{real}} log D ( x ) + {𝔼}_{x \sim {p}_{fake}} log ( 1 - D ( x ) )$$

Given the space layout mask, noise and contextual graph embedding, the image synthesizer 124 may synthesize a rasterized floor plan that follows the generated room positions in the layout graph 106. The Image synthesizer network may include a series of the residual blocks with nearest neighbor upsampling. Since each block operates at a different scale, the space layout mask may be resized to match the resolution of a corresponding feature map using nearest-neighbor downsampling. In this regard, the spectral may be applied to all of the convolutional layers in the image synthesizer 124. The image encoder 200 may encode a real floor plan image to a latent representation for generating a mean vector and a variance vector. The mean vector and the variance vector may be used to determine the noise input to the image synthesizer 124 via reparameterization. The image encoder 200 may include a series of convolutional layers with stride of two, followed by two linear layers that output a mean vector and a variance vector. In order to encourage the generated floor plans not only to appear realistic (e.g., authentic), but to respect the layout graph relationships, a layout context network 204 may be utilized. The layout context network 204 may pool the features generated from a Conv-MPN network. These pooled context features may then be passed to the fully-connected (FC) layer 206 that generates embeddings (contextual graph embedding) that are provided to both the image synthesizer 124 and the discriminator 132 during training.

With respect to loss function, the space layout network analyzer 114 may be trained to minimize the weighted sum of four losses. For example, bounding box loss (L_{b}) may determine the L₂ difference between ground truth and predicted bounding boxes. Mask loss (Lₘ) may determine the L₂ difference between ground truth and predicted masks. Pixel loss (Lₚ) may determine the L₂ difference between ground-truth and generated images. Overlap loss (Lₒ) may determine the overlap between the predicted room bounding boxes. The overlap between room bounding boxes may be specified to be as small as possible. Image adversarial loss (LGAN) may be determined to generate floor plan images that appear realistic.

Loss may be determined as: L_{T}=λ_{b}L_{b}+λₘLₘ+λₚLₚ+λₒLₒ, where λ_{b}=λₘ=λₚ=λ_{b0}=1

The training dataset may include, for example, several thousand vector-graphics floor plans of residential (and/or non-residential) buildings designed by architects. Each floor plan may be represented as a four channel image. The first channel may store inside mask, the second channel may store boundary mask, the third channel may store wall mask, and the fourth channel may store room mask.

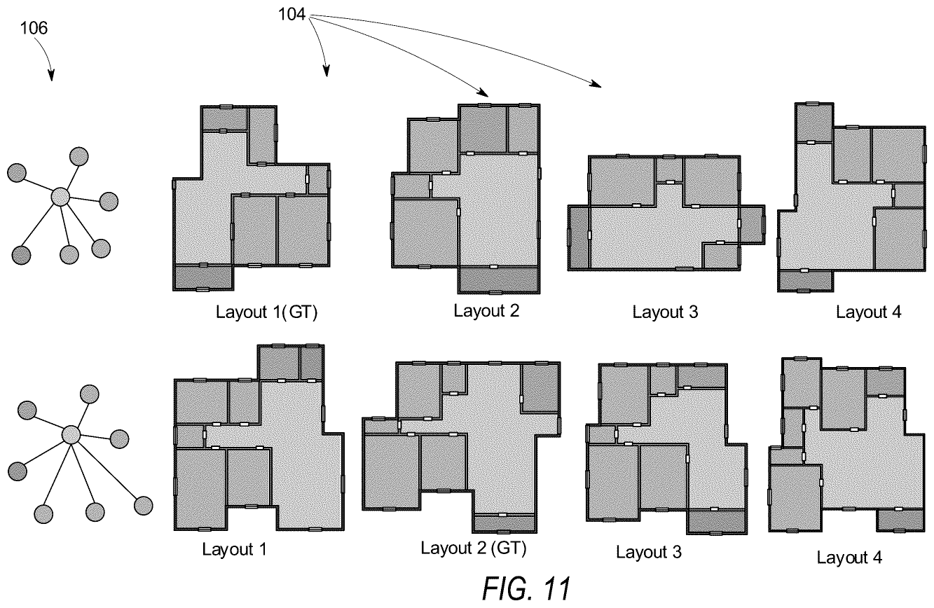

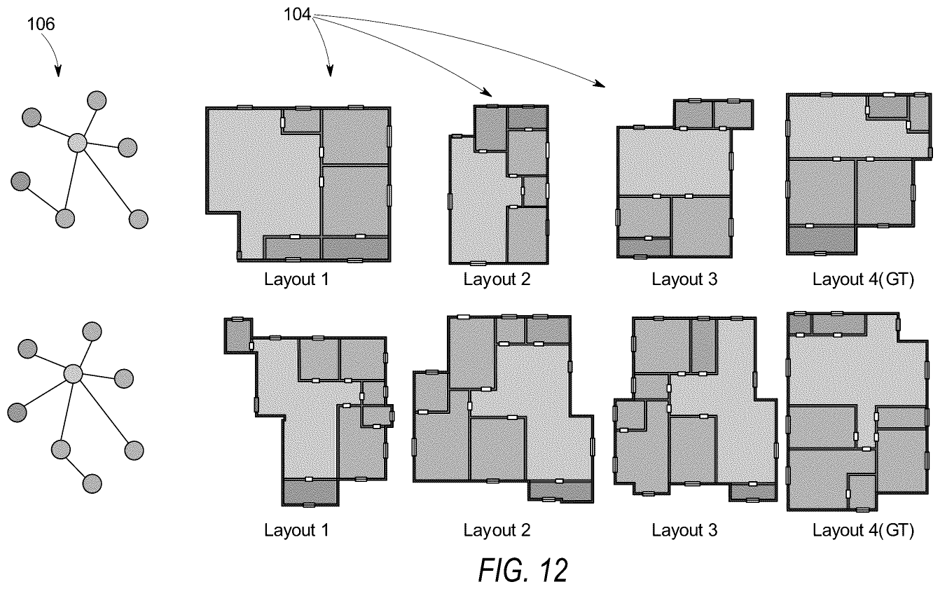

FIGS. 11-12 illustrate examples of results generated by the apparatus 100, in accordance with an example of the present disclosure.

Referring to FIGS. 11-12, the floor plans generated by the apparatus 100 for various input boundaries and user constraints are shown. As shown, the floor plans generated by the apparatus 100 may locate the outline of the layout more precisely. Further, the floor plans generated by the apparatus 100 may meet size requirements of individual rooms and the spatial relations between rooms. The ground truth floor plans may be represented as GT.

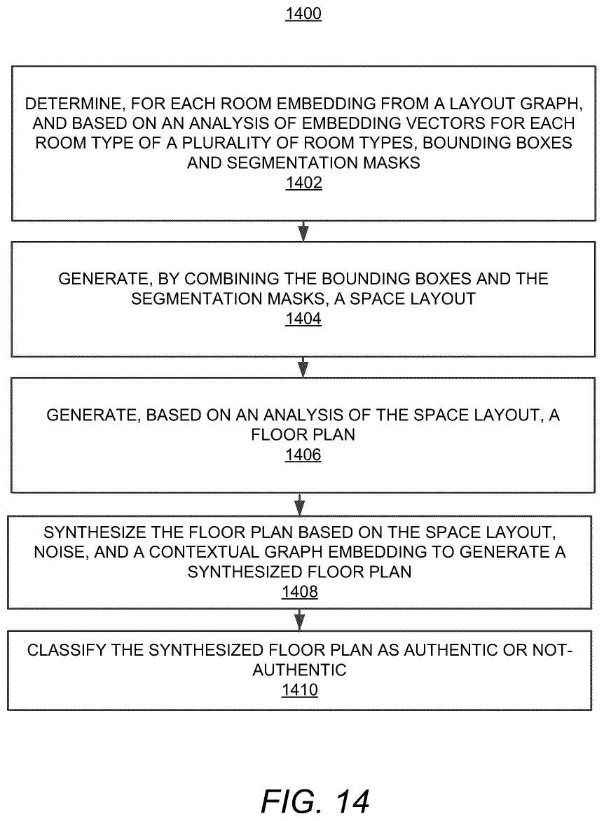

FIGS. 13-15 respectively illustrate an example block diagram 1300, a flowchart of an example method 1400, and a further example block diagram 1500 for generative network-based floor plan generation, according to examples. The block diagram 1300, the method 1400, and the block diagram 1500 may be implemented on the apparatus 100 described above with reference to FIG. 1 by way of example and not of limitation. The block diagram 1300, the method 1400, and the block diagram 1500 may be practiced in other apparatus. In addition to showing the block diagram 1300, FIG. 13 shows hardware of the apparatus 100 that may execute the instructions of the block diagram 1300. The hardware may include a processor 1302, and a memory 1304 storing machine readable instructions that when executed by the processor cause the processor to perform the instructions of the block diagram 1300. The memory 1304 may represent a non-transitory computer readable medium. FIG. 14 may represent an example method for generative network-based floor plan generation, and the steps of the method. FIG. 15 may represent a non-transitory computer readable medium 1502 having stored thereon machine readable instructions to provide generative network-based floor plan generation according to an example. The machine readable instructions, when executed, cause a processor 1504 to perform the instructions of the block diagram 1500 also shown in FIG. 15.

The processor 1302 of FIG. 13 and/or the processor 1504 of FIG. 15 may include a single or multiple processors or other hardware processing circuit, to execute the methods, functions and other processes described herein. These methods, functions and other processes may be embodied as machine readable instructions stored on a computer readable medium, which may be non-transitory (e.g., the non-transitory computer readable medium 1502 of FIG. 15), such as hardware storage devices (e.g., RAM (random access memory), ROM (read only memory), EPROM (erasable, programmable ROM), EEPROM (electrically erasable, programmable ROM), hard drives, and flash memory). The memory 1304 may include a RAM, where the machine readable instructions and data for a processor may reside during runtime.

Referring to FIGS. 1-13, and particularly to the block diagram 1300 shown in FIG. 13, the memory 1304 may include instructions 1306 to receive, for a floor plan 104 that is to be classified, a layout graph 106 for which user constraints 108 are encoded as a plurality of room types 110.

The processor 1302 may fetch, decode, and execute the instructions 1308 to generate, based on the layout graph 106, embedding vectors 112 for each room type of the plurality of room types 110.

The processor 1302 may fetch, decode, and execute the instructions 1310 to determine, for each room embedding 116 from the layout graph 106, and based on an analysis of the embedding vectors 112 for each room type of the plurality of room types 110, bounding boxes 118 and segmentation masks 120.

The processor 1302 may fetch, decode, and execute the instructions 1312 to generate, by combining the bounding boxes 118 and the segmentation masks 120, a space layout 122.

The processor 1302 may fetch, decode, and execute the instructions 1314 to generate, based on an analysis of the space layout 122, the floor plan 104.

The processor 1302 may fetch, decode, and execute the instructions 1316 to synthesize the floor plan 104 based on the space layout 122, noise 126, and a contextual graph embedding 128 to generate a synthesized floor plan 130.

The processor 1302 may fetch, decode, and execute the instructions 1318 to classify the synthesized floor plan 104 as authentic 134 or not-authentic 136.

Referring to FIGS. 1-12 and 14, and particularly FIG. 14, for the method 1400, at block 1402, the method may include determining, for each room embedding 116 from a layout graph 106, and based on an analysis of embedding vectors 112 for each room type of a plurality of room types 110, bounding boxes 118 and segmentation masks 120.

At block 1404, the method may include generating, by combining the bounding boxes 118 and the segmentation masks 120, a space layout 122.

At block 1406, the method may include generating, based on an analysis of the space layout 122, a floor plan 104.

At block 1408, the method may include synthesizing the floor plan 104 based on the space layout 122, noise 126, and a contextual graph embedding 128 to generate a synthesized floor plan 130.

At block 1410, the method may include classifying the synthesized floor plan 104 as authentic 134 or not-authentic 136.

Referring to FIGS. 1-12 and 15, and particularly FIG. 15, for the block diagram 1500, the non-transitory computer readable medium 1502 may include instructions 1506 to determine, for each room embedding 116 from a layout graph 106, and based on an analysis of embedding vectors 112 for each room type of a plurality of room types 110, a space layout 122.

The processor 1504 may fetch, decode, and execute the instructions 1508 to generate, based on an analysis of the space layout 122, a floor plan 104.

The processor 1504 may fetch, decode, and execute the instructions 1510 to synthesize the floor plan 104 based on at least one of the space layout 122, noise 126, or a contextual graph embedding 128 to generate a synthesized floor plan 130.

The processor 1504 may fetch, decode, and execute the instructions 1512 to classify the synthesized floor plan 104 as authentic 134 or not-authentic 136.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims—and their equivalents—in which all terms are meant in their broadest reasonable sense unless otherwise indicated.

What is claimed is:

1. A generative network-based floor plan generation apparatus comprising:
at least one hardware processor;
a graph convolutional message passing network analyzer, executed by the at least one hardware processor, to:
receive, for a floor plan that is to be classified, a layout graph for which user constraints are encoded as a plurality of room types, wherein the user constraints include spatial connections therebetween; and
generate, based on the layout graph, embedding vectors for each room type of the plurality of room types;
a space layout network analyzer, executed by the at least one hardware processor, to:
determine, for each room embedding from the layout graph, and based on an analysis of the embedding vectors for each room type of the plurality of room types, bounding boxes and segmentation masks; and
generate, by combining the bounding boxes and the segmentation masks, a space layout;
an image synthesizer, executed by the at least one hardware processor, to:
generate, based on an analysis of the space layout, the floor plan; and
synthesize the floor plan based on the space layout, noise, and a contextual graph embedding to generate a synthesized floor plan; and
a discriminator, executed by the at least one hardware processor, to classify the synthesized floor plan as authentic or not-authentic.

2. The generative network-based floor plan generation apparatus according to claim 1, further comprising:
an image encoder, executed by the at least one hardware processor, to:
generate, based on the floor plan, mean and variance vectors; and
determine, based on the mean and variance vectors, the noise.

3. The generative network-based floor plan generation apparatus according to claim 1,
wherein the image synthesizer is executed by the at least one hardware processor to:
receive an input boundary feature map; and
generate, based on an analysis of the space layout and the input boundary feature map, the floor plan.

4. The generative network-based floor plan generation apparatus according to claim 1, wherein the graph convolutional message passing network analyzer is executed by the at least one hardware processor to generate, based on the layout graph, the embedding vectors for each room type of the plurality of room types by:
passing the layout graph through a series of graph convolution layers to embed the plurality of room types and relationships between the plurality of room types in the layout graph; and
generating, based on the embedded plurality of room types and the relationships between the plurality of room types in the layout graph, the embedding vectors.

5. The generative network-based floor plan generation apparatus according to claim 1, wherein the space layout network analyzer is executed by the at least one hardware processor to determine, for each room embedding from the layout graph, and based on the analysis of the embedding vectors for each room type of the plurality of room types, bounding boxes and segmentation masks by:
passing the embedding vectors for each room type of the plurality of room types to a mask regression network to determine the bounding boxes and segmentation masks.

6. The generative network-based floor plan generation apparatus according to claim wherein the mask regression network includes a sequence of upsampling and convolution layers.

7. The generative network-based floor plan generation apparatus according to claim 1, wherein the image synthesizer includes a series of residual blocks with nearest neighbor upsampling layers.

8. The generative network-based floor plan generation apparatus according to claim 1, wherein the discriminator is executed by the at least one hardware processor, to classify the synthesized floor plan as authentic or not-authentic by:
training an image generation network adversarially against a discriminator network.

9. A method for generative network-based floor plan generation, the method comprising:
determining, by at least one hardware processor, for each room embedding from a layout graph, and based on an analysis of embedding vectors for each room type of a plurality of room types, bounding boxes and segmentation masks;
generating, by the at least one hardware processor, by combining the bounding boxes and the segmentation masks, a space layout;
generating, by the at least one hardware processor, based on an analysis of the space layout, a floor plan;
synthesizing, by the at least one hardware processor, the floor plan based on the space layout, noise, and a contextual graph embedding to generate a synthesized floor plan; and
classifying, by the at least one hardware processor, the synthesized floor plan as authentic or not-authentic.

10. The method for generative network-based floor plan generation according to claim 9, further comprising:
receiving, by the at least one hardware processor, for the floor plan that is to be classified, the layout graph for which user constraints are encoded as the plurality of room types, wherein the user constraints include spatial connections therebetween.

11. The method for generative network-based floor plan generation according to claim 9, further comprising:
generating, by the at least one hardware processor, based on the layout graph, the embedding vectors for each room type of the plurality of room types.

12. The method for generative network-based floor plan generation according to claim 11, wherein generating, by the at least one hardware processor, based on the layout graph, the embedding vectors for each room type of the plurality of room types, further comprises:
passing, by the at least one hardware processor, the layout graph through a series of graph convolution layers to embed the plurality of room types and relationships between the plurality of room types in the layout graph; and
generating, by the at least one hardware processor, based on the embedded plurality of room types and the relationships between the plurality of room types in the layout graph, the embedding vectors.

13. The method for generative network-based floor plan generation according to claim 9, further comprising:
generating, by the at least one hardware processor, based on the floor plan, mean and variance vectors; and
determining, by the at least one hardware processor, based on the mean and variance vectors, the noise.

14. The method for generative network-based floor plan generation according to claim 9, wherein generating, by the at least one hardware processor, based on the analysis of the space layout, the floor plan, further comprises:
receiving, by the at least one hardware processor, an input boundary feature map; and
generating, by the at least one hardware processor, based on an analysis of the space layout and the input boundary feature map, the floor plan.

15. A non-transitory computer readable medium having stored thereon machine readable instructions, the machine readable instructions, when executed by at least one hardware processor, cause the at least one hardware processor to:
determine, for each room embedding from a layout graph, and based on an analysis of embedding vectors for each room type of a plurality of room types, a space layout;
generate, based on an analysis of the space layout, a floor plan;
synthesize the floor plan based on at least one of the space layout, noise, or a contextual graph embedding to generate a synthesized floor plan; and
classify the synthesized floor plan as authentic or not-authentic.

16. The non-transitory computer readable medium according to claim 15, wherein the machine readable instructions, when executed by the at least one hardware processor, further cause the at least one hardware processor to:
receive, for the floor plan that is to be classified, the layout graph for which user constraints are encoded as the plurality of room types, wherein the user constraints include spatial connections therebetween.

17. The non-transitory computer readable medium according to claim 15, wherein the machine readable instructions, when executed by the at least one hardware processor, further cause the at least one hardware processor to:
generate, based on the layout graph, the embedding vectors for each room type of the plurality of room types.

18. The non-transitory computer readable medium according to claim 15, wherein the machine readable instructions to determine, for each room embedding from the layout graph, and based on the analysis of the embedding vectors for each room type of the plurality of room types, the space layout, when executed by the at least one hardware processor, further cause the at least one hardware processor to:
determine, for each room embedding from the layout graph, and based on the analysis of the embedding vectors for each room type of the plurality of room types, bounding boxes and segmentation masks; and
generate, by combining the bounding boxes and the segmentation masks, the space layout.

19. The non-transitory computer readable medium according to claim 18, wherein the machine readable instructions to determine, for each room embedding from the layout graph, and based on the analysis of the embedding vectors for each room type of the plurality of room types, bounding boxes and segmentation masks, when executed by the at least one hardware processor, further cause the at least one hardware processor to:
pass the embedding vectors for each room type of the plurality of room types to a mask regression network to determine the bounding boxes and segmentation masks.

20. The non-transitory computer readable medium according to claim 19, wherein the mask regression network includes a sequence of upsampling and convolution layers.
